(19) United States
(12) Patent Application Publication
(10) Pub. No.: US 2014/0272350 A1
(43) Pub. Date: Sep. 18, 2014

(54) GAS BARRIER FILM INCLUDING GRAPHENE LAYER, FLEXIBLE SUBSTRATE INCLUDING THE SAME, AND MANUFACTURING METHOD THEREOF

(71) Applicant: CHEIL INDUSTRIES INC., Gumi-si, Gyeongsangbuk-do (KR)

(72) Inventors: Tae Ho Kim, Uiwang-si (KR); Young Kwon Kim, Uiwang-si (KR); Seung Beom Kee, Uiwang-si (KR); Sung Kook Kim, Uiwang-si (KR); Chang Gyu Im, Uiwang-si (KR)

(73) Assignee: Cheil Industries Inc., Gumi-si (KR)

(21) Appl. No.: 14/354,905

(22) PCT Filed: Sep. 28, 2012
(86) PCT No.: PCT/KR2012/007882

§ 371 Date: Apr. 28, 2014

(30) Foreign Application Priority Data
Oct. 28, 2011 (KR) 10-2011-0111673

(51) Int. Cl. G02F 1/1339; H01L 51/52; C23C 16/26

(52) U.S. Cl. CPC G02F 1/1339; C23C 16/26; H01L 51/5253
USPC 428/213; 428/408; 428/336; 427/240; 427/430.1; 427/249.1; 427/427; 427/420

(57) ABSTRACT

The present invention relates to a gas barrier film, a flexible substrate including the same, and a manufacturing method thereof. More specifically, a barrier film of the present invention relates to a first polymer layer, a gas barrier film including a graphene layer formed on the first polymer layer, a flexible substrate including the same, and a manufacturing method thereof.

### TECHNICAL FIELD

The present invention relates to a gas barrier film, a flexible substrate including the same, and a method of manufacturing the same. More particularly, the present invention relates to a gas barrier film including a graphene layer, a flexible substrate including the gas barrier film, and a method of manufacturing the same.

### BACKGROUND ART

In a display panel, a gas barrier film mainly serves to prevent infiltration of gas and vapor through a polymeric material. In addition, the gas barrier film requires general properties of an outer skin for organic displays, such as heat resistance, low roughness, and ease of commercial production by low processing costs and the like. Background techniques relating to a gas barrier film for displays are disclosed in Korean Patent Laid-open Publication No. 2004-7002488 and Japanese Patent Laid-open Publication No. 2010-201628.

Conventionally, a laminate structure of metal oxide gas barrier films is used for application to displays, such as LCD, OLED, and the like. However, since the gas barrier films are likely to be separated from each other due to poor interfacial adhesion to a transparent polymer, that is, an organic material, the laminate structure of the metal oxide gas barrier films is difficult to use in a flexible display.

On the other hand, graphene refers to a one-layer structure in which carbon atoms are continuously arranged in benzene ring form (two-dimensional carbon structure having a thickness of about 4 Å), and is constituted with C₆₀, carbon nanotubes, and graphite. In graphite as a representative layered material, although bonding between carbon atoms constituting graphene in each layer (this bonding is referred to as ‘sigma-bonding’) is very strong covalent bonding, bonding between graphene layers (this bonding is referred to as ‘pi-bonding’) is very week van der Waals bonding. Due to such characteristics, there can be a free-layer graphene of a very thin two-dimensional structure having a thickness of about 4 Å In other words, graphene layers can be separated into individual graphene layer when pi-bonding between the graphene layers is broken. Single layer graphene, which forms part of carbon nanotubes, has a smaller size than carbon nanotubes and exhibits excellent properties. As such, graphene is an ideal substitute for carbon nanotubes. A background technique relating to graphene is disclosed in Korean Patent Laid-open Publication No. 2011-0044617.

In the related art, various attempts have been made to use a graphene/polymer nano-composite as a gas barrier film. However, the gas barrier film formed of the graphene/polymer nano-composite does not provide a sufficient gas barrier effect due to insufficient dispersion of graphene in the polymer resin.

### DISCLOSURE

### Technical Problem

It is an aspect of the present invention to provide a gas barrier film which includes a graphene layer and is applicable to a flexible display.

It is another aspect of the present invention to provide a gas barrier film which has excellent light transmittance.

It is a further aspect of the present invention to provide a gas barrier film having excellent gas and water vapor blocking effects.

It is yet another aspect of the present invention to provide a flexible substrate including the gas barrier film.

It is yet another aspect of the present invention to provide a method of manufacturing a gas barrier film including a graphene layer and a method of manufacturing a flexible substrate including the same.

### Technical Solution

In accordance with one aspect of the present invention, a gas barrier film may include: a polymer film; and a first graphene layer formed on the polymer film.

The first graphene layer may have a thickness of about 0.4 nm to about 5 nm.

The first graphene layer may be formed as a single layer or multiple layers.

The polymer film may include at least one selected from polyorganosiloxane, polyolefin, ethylene-propylene copolymers, polyester, polyamide, polyvinylacetate, polycarbonate, polyvinylchloride, acrylic, fluorinated polyolefin, aromatic vinyl polymers, polyimide, epoxy resins, and polyurethane.

The first graphene layer may further include a metal oxide.

The gas barrier film may further include a first organic layer formed on the first graphene layer.

The gas barrier film may further include at least one sequential stack structure of a second graphene layer and a second organic layer on the first organic layer.

The gas barrier film may further include a metal layer on the first graphene layer, wherein the metal layer includes at least one of a metal, a metal oxide, and a metal nitride.

The metal layer may adjoin the first graphene layer.

The gas barrier film may further include a first organic layer formed between the first graphene layer and the metal layer.

The gas barrier film may further include a second organic layer formed on the metal layer.

The first organic layer and the second organic layer may include at least one selected from polyorganosiloxane, polyolefin, ethylene-propylene copolymers, polyester, polyamide, polyvinylacetate, polycarbonate, polyvinylchloride, acrylic, fluorinated polyolefin, aromatic vinyl polymers, polyimide, epoxy resins, and polyurethane.

The metal may include at least one selected from aluminum, silicon, indium, tin, and zinc.

Each of the first organic layer and the second organic layer may have a thickness of about 0.01 μm to about 10 μm.

The gas barrier film may have a light transmittance of about 76% or more at a wavelength of 550 nm.

The gas barrier film may have a water vapor transmission rate of about 10⁻⁶ to about 1 cc/m²·day, as measured at 23° C. and 70% relative humidity for 100 hours.

The gas barrier film may have an oxygen transmission rate of about 10⁻⁵ to about 1 cc/m²·day, as measured at 23° C. and 70% relative humidity for 100 hours.

In accordance with another aspect of the present invention, a flexible substrate may include the gas barrier film.

In accordance with a further aspect of the present invention, a method of manufacturing a gas barrier film may include coating a graphene solution onto a polymer film to form a graphene layer on the polymer film. Here, the coating may include at least one selected from spin coating, dip coating, solvent casting, chemical vapor deposition, slot die coating, and spray coating.

### Advantageous Effects

The present invention provides a gas barrier film that is applicable to a flexible display, and has excellent light transmittance and excellent gas and water vapor blocking effects.

### DESCRIPTION OF DRAWINGS

FIG. 1 is a cross-sectional view of a gas barrier film according to one embodiment of the present invention.

FIG. 2 is a cross-sectional view of a gas barrier film according to another embodiment of the present invention.

FIG. 3 is a cross-sectional view of a gas barrier film according to a further embodiment of the present invention.

FIG. 4 is a cross-sectional view of a gas barrier film according to yet another embodiment of the present invention.

### BEST MODE

As used herein, it will be understood that, when a layer is referred to as being placed “on” another layer, the layer can be directly placed on the other layer, or an intervening layer(s) may also be present

In accordance with one aspect of the present invention, a gas barrier film may include a polymer film; and a first graphene layer formed on the polymer film.

A typical gas barrier film including a metal oxide is formed by stacking the metal oxide. However, low interfacial adhesion between the metal oxide and a polymer film, that is, an organic molecule, causes delamination and film breakage upon film bending. For such reasons, the typical gas barrier film is not suitable for a flexible display.

On the other hand, the gas barrier film according to the invention includes graphene to solve such problems.

Graphene has a two-dimensional structure in which carbon atoms are continuously arranged in benzene ring form, and exhibit different properties than graphite having a three dimensional connection structure. Graphene and graphite can be distinguished from each other by X-ray diffraction. The graphene layer may include graphene having a two-dimensional structure instead of graphite.

The first graphene layer may include about 99% or more of graphene, preferably about 99% to about 100% of graphene. As a result, the graphene layer does not exhibit peaks of graphite or graphite oxide in X-ray diffraction.

Graphene of the first graphene layer may be obtained from graphite through oxidation reduction method, but is not limited thereto. A graphene solution is prepared by dispersing graphene in a solvent and is coated onto a polymer film to form the first graphene layer. The graphene solution may include about 0.001 wt % to about 30 wt % of graphene.

The first graphene layer may be a graphene monolayer (thickness: about 4□) or may be a multilayered structure of graphene, which is formed by stacking several graphene layers. Specifically, the graphene layer may be a graphene monolayer, or may be a multilayered structure of graphene, which is formed by stacking several graphene monolayers. Even when the first graphene layer has the multilayered structure, the first graphene layer preferably has an overall thickness of about 5 nm or less in order to secure light transmittance.

The first graphene layer has a thickness of about 0.4 nm to about 5 nm, preferably from about 0.4 nm to about 2 nm. Within this thickness range of the first graphene layer, the gas barrier film can be applied to a gas barrier film and can secure light transmittance.

The first graphene layer may further include a metal oxide. The metal oxide may include at least one of silicon oxide, aluminum oxide, indium tin oxide (ITO), and indium zinc oxide (IZO).

The polymer film may be any transparent polymer film typically used in the gas barrier film. For example, the polymer film may include at least one selected from polyorganosiloxane, polyolefin, ethylene-propylene copolymer, polyester, polyamide, polyvinylacetate, polycarbonate, polyvinylchloride, acrylic, fluorinated polyolefin, aromatic vinyl polymer, polyimide, epoxy, and polyurethane resins.

The polyorganosiloxane may include polysiloxane comprising a unit represented by Formula 1:

[chemical structure]

(wherein Rₐ and R_{b} are a hydrogen atom, a C₁ to C₂₀ alkyl group, a C₂ to C₂₀ alkenyl group, a C₂ to C₂₀ alkynyl group, a C₁ to C₂₀ alkoxy group, a C₃ to C₃₀ cycloalkyl group, a C₃ to C₃₀ cycloalkenyl group, a C₃ to C₃₀ cycloalkynyl group, a C₆ to C₃₀ aryl group, or a C₆ to C₃₀ aryloxy group; and n is an integer from 2 to 1000).

The polyorganosiloxane may include a terminal group represented by Formula Ia or Ib:

R₁R₂R₃SiO— <Formula Ia>

R₄R₅R₆Si— <Formula Ib>

(wherein R₁, R₂, R₃, R₄, R₅, and R₆ are each independently a hydrogen atom, a C₁ to C₂₀ alkyl group, a C₂ to C₂₀ alkenyl group, a C₂ to C₂₀ alkynyl group, a C₁ to C₂₀ alkoxy group, a C₃ to C₃₀ cycloalkyl group, a C₃ to C₃₀ cycloalkenyl group, a C₃ to C₃₀ cycloalkynyl group, a C₆ to C₃₀ aryl group, a C₆ to C₃₀ aryloxy group, or a UV curing functional group)

In some embodiments, the polyorganosiloxane may include polydimethylsiloxane (PDMS), without being limited thereto.

The polyolefin may be polyethylene or polypropylene.

The acrylic resin may include polymethyl methacrylate or polymethyl acrylate.

The fluorinated polyolefin may include, for example, fluorinated polyethylene.

The aromatic vinyl polymer may include polystyrene or styrene-acrylonitrile copolymers.

The polymer film may have a thickness of about 30 μm to about 200 μm. Within this thickness range, the polymer film may be applied to the gas barrier film.

The first graphene layer may be formed on a portion or an overall upper surface of the polymer film.

The gas barrier film may further include at least one of a first organic layer, a second organic layer, a second graphene layer and a metal layer on the first graphene layer.

In one embodiment, the gas barrier film may further include a first organic layer on the first graphene layer.

In one embodiment, the gas barrier film may further include at least one sequential stack structure of a second graphene layer and a second organic layer on the first organic layer.

In another embodiment, the gas barrier film may further include a metal layer on the first graphene layer, wherein the metal layer includes at least one of a metal, a metal oxide, and a metal nitride.

In one embodiment, the metal layer may adjoin the first graphene layer.

The gas barrier film may further include a first organic layer between the first graphene layer and the metal layer.

In another embodiment, the gas barrier film may further include a second organic layer on the metal layer.

The first organic layer and the second organic layer may be formed of the same or different materials. In addition, the polymer film, the first organic layer, and the second organic layer may be formed of the same or different materials.

For example, the first organic layer and the second organic layer may include at least one selected from polyorganosiloxane, polyolefin, ethylene-propylene copolymer, polyester, polyamide, polyvinyl acetate, polycarbonate, polyvinyl chloride, acrylic, fluorinated polyolefin, aromatic vinyl polymer, polyimide, epoxy, and polyurethane resins.

The polymer film may have a thickness of about 30 μm to about 200 μm, and the first organic layer or the second organic layer may have a thickness of about 0.01 μm to about 10 μm. Within this thickness range, the gas barrier film can minimize loss of light transmittance.

The thickness of the polymer film may be about 3 to 2000 times the thickness of the first organic layer or the second organic layer. Within this thickness range, the gas barrier film can minimize loss of light transmittance.

The first organic layer and second organic layer may be formed by a typical method. For example, the first organic layer or second organic layer may be formed by coating a polymer for the first organic layer or a polymer for the second organic layer, respectively, followed by curing. Curing may be performed by any method known in the art, for example, by heat curing or UV curing, using a curing catalyst and the like.

Details of the second graphene layer are the same as those of the first graphene layer described above.

The second graphene layer may have a thickness from about 0.4 nm to about 5 nm, preferably from about 0.4 nm to about 2 nm.

The second graphene layer may be formed by coating a graphene solution as described above.

In the metal layer, the metal may include at least one selected from silicon, aluminum, indium, tin, and zinc. As the metal layer is further stacked on the gas barrier film, it is possible to prevent generation of defect which can have a significant influence on water vapor and oxygen transmission of the gas barrier film.

Specifically, the metal layer may include at least one selected from silicon nitride, silicon oxide, silicon carbide, aluminum nitride, aluminum oxide, ITO, and IZO.

The metal layer may have a thickness from about 5 nm to about 200 nm, preferably from about 5 nm to about 50 nm. Within this thickness range, the gas barrier film can minimize loss of light transmittance.

The metal layer may be deposited by any method, for example, chemical vapor deposition (CVD).

FIG. 1 to FIG. 4 are cross-sectional views of gas barrier films according to embodiments of the present invention.

FIG. 1 shows a gas barrier film in which a first graphene layer 2 and a first organic layer 12 are sequentially stacked on a polymer film 1.

FIG. 2 shows a gas barrier film in which a first graphene layer 11, a first organic layer 12, a second graphene layer 13, and a second organic layer 15 are sequentially stacked on a polymer film 1.

FIG. 3 shows a gas barrier film in which a first graphene layer 11, a first organic layer 12, a metal layer 14, and a second organic layer 15 are sequentially stacked on a polymer film 1.

FIG. 4 shows a gas barrier film in which a first graphene layer 11, a metal layer 14, and a second organic layer 15 are sequentially stacked on a polymer film 1.

As shown in FIG. 1 to FIG. 4, the polymer film, the first graphene layer, the organic layers including the first organic layer, the second organic layer, and the like, and the graphene layer are alternately stacked to form an elongated infiltration path of water vapor and oxygen, thereby securing sufficient water vapor and oxygen transmission without affecting light transmittance.

The gas barrier film may have a light transmittance of about 76% or more at a wavelength of 550 nm, preferably about 87% or more, more preferably about 87% to about 100%. Within this range of light transmittance, the gas barrier film can be used in the flexible substrate.

The gas barrier film may have a water vapor transmission rate of about 10⁻⁶ to about 1 cc/m²·day, preferably about 10⁻⁶ to about 10⁻¹ cc/m²·day, as measured at a thickness of 100 nm. Within this range of water vapor transmission rate, the gas barrier film can be used in the flexible substrate.

The gas barrier film may have an oxygen transmission rate of about 10⁻⁵ to about 1 cc/m²·day, preferably about 10⁻⁵ to about 8×10⁻¹ cc/m²·day, as measured at a thickness of 100 nm. Within this range of oxygen transmission rate, the gas barrier film can be used in the flexible substrate.

The gas barrier film may be included in the flexible substrate and acts as a film for blocking water vapor or oxygen.

In accordance with another aspect of the invention, a method of manufacturing a gas barrier film may include coating a graphene solution onto a polymer film.

The graphene solution is prepared by dispersing graphene in a solvent. The solvent may be distilled water, ethyl alcohol, methyl alcohol, dimethylformamide, acetone, tetrahydrofuran, dimethylsulfoxide, acetonitrile, dichlorobenzene, diethylether, toluene, methylpyrrolidone, and the like.

In the graphene solution, graphene may be present in an amount of about 0.001 wt % to about 30 wt %, preferably about 0.01 wt % to about 10 wt %. Within this content range of graphene, the graphene layer can be easily formed.

Coating may be performed by spin coating, dip coating, solvent casting, chemical vapor deposition, slot die coating, spray coating, and the like.

The graphene solution may be coated once or more to form a graphene layer having a thickness from about 0.4 nm to about 5 nm.

In accordance with a further aspect of the invention, a flexible substrate may include the gas barrier film according to the present invention. Since the gas barrier film is included in the flexible substrate, the flexible substrate can secure an excellent gas blocking effect therein, improved adhesion, and light transmittance.

In accordance with yet another aspect of the invention, a display may include the flexible substrate. For example, the display is an optical display.

### Mode for Invention

Hereinafter, the present invention will be described in more detail with reference to some examples. It should be understood that these examples are provided for illustration only and are not to be construed in any way as limiting the present invention.

### Example 1

Graphene was prepared from graphite through oxidation reduction method and a graphene solution containing 0.01 wt % of graphene was prepared. The graphene solution was coated to a thickness of 1 nm onto a 100 μm thick polydimethylsiloxane (PDMS) polymer film using a spin coater to form a first graphene layer. PDMS was coated onto the first graphene layer to a thickness of 1 μm using a spin coater and cured, thereby forming a gas barrier film in which the polymer film, the first graphene layer and the PDMS layer (first organic layer) were sequentially stacked from bottom to top.

### Example 2

A second graphene layer (thickness: 1 nm) and a PDMS layer (second organic layer) (thickness: 1 μm) were formed in the same manner on the PDMS layer (first organic layer) of Example 1, thereby forming a gas barrier film in which the polymer film, the first graphene layer, the PDMS layer (first organic layer), the second graphene layer, and the PDMS layer (second organic layer) were sequentially stacked from bottom to top.

### Example 3

An aluminum oxide (Al₂O₃) layer (metal layer) was formed to a thickness of 100 nm on the PDMS layer (first organic layer) of Example 1 by chemical vapor deposition (CVD), and a PDMS layer (second organic layer) was formed thereon to a thickness of 1 μm in the same manner, thereby forming a gas barrier film in which the polymer film, the first graphene layer, the PDMS layer (first organic layer), the aluminum oxide layer (metal layer), and the PDMS layer (second organic layer) were sequentially stacked from bottom to top.

### Example 4

An aluminum oxide (Al₂O₃) layer (metal layer) was formed to a thickness of 100 nm on the first graphene layer of Example 1 by chemical vapor deposition (CVD), and a PDMS layer (second organic layer) was formed thereon to a thickness of 1 μm in the same manner, thereby forming a gas barrier film in which the polymer film, the first graphene layer, the aluminum oxide layer (metal layer), and the PDMS layer (second organic layer) were sequentially stacked from bottom to top.

### Comparative Example 1

A graphite solution was coated onto a 100 μm thick PDMS polymer film to form a graphite layer (thickness: 1 μm), followed by forming a 1 nm thick PDMS layer thereon, thereby forming a gas barrier film in which the polymer film, the graphite layer and the PDMS layer (first organic layer) were sequentially stacked from bottom to top.

Table 1 shows comparison results of performance of the barrier films prepared in Examples 1 to 4 and Comparative Example 1.

TABLE 1

| | | Water vapor | Oxygen | |
|---|---|---|---|---|
| | | transmission | transmission | |
| | Light | rate | rate | Bending |
| | transmittance (%) | (cc/m² · day) | (cc/m² · day) | resistance |
| Example 1 | 90 | 9 × 10⁻² | 0.8 | Pass |
| Example 2 | 87 | 6 × 10⁻³ | 5 × 10⁻² | Pass |
| Example 3 | 88 | 3 × 10⁻³ | 2 × 10⁻² | Pass |
| Example 4 | 89 | 5 × 10⁻³ | 3 × 10⁻² | Pass |
| Comparative | 75 | 80 | 96 | Fail |
| Example 1 | | | | |

Light transmittance, water vapor transmission rate, oxygen transmission rate and bending resistance were evaluated as follows.

(1) Light transmittance: Light transmittance was measured at a wavelength of 550 nm using a UV/VIS spectrometer (PerkinElmer, Lambda 45).

(2) Water vapor transmission rate: Water vapor transmission rate was measured using a Water vapor transmission rate tester (PERMATRAN-W® Model 3/33) in accordance with the ASTM F 1249. A prepared specimen was cut to a size of 100 mm×100 mm×100 μm (length×width×thickness), and was fitted into a jig, the center of which is perforated. Measurement was performed under conditions of 23° C. and 100% relative humidity for 100 hours.

(3) Oxygen transmission rate: Oxygen transmission rate was measured using an oxygen transmission rate tester (OX-TRAN® Model 2/21) in accordance with the ASTM D 3985. A prepared specimen was cut to a size of 100 mm×100 mm×100 μm (length×width×thickness) and was fitted into a jig, the center of which is perforated. Measurement was performed under conditions of 23° C. and 100% relative humidity for 100 hours.

(4) Bending resistance: Bending resistance was measured by a bending test to confirm durability of a gas barrier film. A bending tester was fabricated in accordance with ASTM D2236, and a gas barrier film was cut to a size of 100 mm×30 mm to prepare a specimen. Then, with the longitudinal direction of the specimen set to a mechanical movement direction of the film, the bending test was performed at a radius of 7 mm for 1000 cycles.

The gas barrier films according to the present invention had a light transmittance of 87˜90%, which is higher than that of the gas barrier film of Comparative Example 1, and had much better moisture permeability and oxygen permeability than the gas barrier film of Comparative Example 1. Further, in the bending resistance test for 1000 cycles, there was no problem in the gas barrier film according to the present invention, unlike the gas barrier film of Comparative Example 1.

Although the present invention has been described with reference to some embodiments in conjunction with the accompanying drawings, it should be understood that the present invention is not limited thereto and may be embodied in different ways, and that various modifications, changes, alterations, and equivalent embodiments can be made by those skilled in the art without departing from the spirit and scope of the present invention. Therefore, it should be understood that the embodiments and the accompanying drawings are provided for illustration only and are not construed in any way as limiting the present invention.

1. A gas barrier film comprising:
a polymer film; and
a first graphene layer formed on the polymer film.

2. The gas barrier film according to claim 1, wherein the first graphene layer has a thickness of about 0.4 nm to about 5 nm.

3. The gas barrier film according to claim 1, wherein the first graphene layer is formed as a single layer or multiple layers.

4. The gas barrier film according to claim 1, wherein the polymer film comprises at least one selected from polyorganosiloxane, polyolefin, ethylene-propylene copolymers, polyester, polyamide, polyvinylacetate, polycarbonate, polyvinylchloride, acrylic, fluorinated polyolefin, aromatic vinyl polymers, polyimide, epoxy resins, and polyurethane.

5. The gas barrier film according to claim 1, wherein the first graphene layer further comprises a metal oxide.

6. The gas barrier film according to claim 5, further comprising:
a first organic layer formed on the first graphene layer.

7. The gas barrier film according to claim 6, further comprising:
at least one sequential stack structure of a second graphene layer and a second organic layer formed on the first organic layer.

8. The gas barrier film according to claim 1, further comprising:
a metal layer on the first graphene layer, the metal layer comprising at least one of a metal, a metal oxide, and a metal nitride.

9. The gas barrier film according to claim 8, wherein the metal layer adjoins the first graphene layer.

10. The gas barrier film according to claim 8, further comprising:
a first organic layer formed between the first graphene layer and the metal layer.

11. The gas barrier film according to claim 9, further comprising:
a second organic layer formed on the metal layer.

12. The gas barrier film according to claim 6, wherein the first organic layer comprises at least one selected from polyorganosiloxane, polyolefin, ethylene-propylene copolymers, polyester, polyamide, polyvinylacetate, polycarbonate, polyvinylchloride, acrylic polymer, fluorinated polyolefin, aromatic vinyl polymers, polyimide, epoxy resins, and polyurethane.

13. The gas barrier film according to claim 7, wherein the second organic layer comprises at least one selected from polyorganosiloxane, polyolefin, ethylene-propylene copolymers, polyester, polyamide, polyvinylacetate, polycarbonate, polyvinylchloride, acrylic polymer, fluorinated polyolefin, aromatic vinyl polymers, polyimide, epoxy resins, and polyurethane.

14. The gas barrier film according to claim 8, wherein the metal comprises at least one selected from aluminum, silicon, indium, tin, and zinc.

15. The gas barrier film according to claim 6, wherein the first organic layer has a thickness of about 0.01 μm to about 10 μm.

16. The gas barrier film according to claim 7, wherein the second organic layer has a thickness of about 0.01 μm to about 10 μm.

17. The gas barrier film according to claim 6, wherein the polymer film has a thickness about 3 to 2,000 times greater than the thickness of the first organic layer.

18. The gas barrier film according to claim 7, wherein the polymer film has a thickness about 3 to 2,000 times greater than the thickness of the second organic layer.

19. The gas barrier film according to claim 1, wherein the gas barrier film has a light transmittance of about 76% or more at a wavelength of 550 nm.

20. The gas barrier film according to claim 1, wherein the gas barrier film has a water vapor transmission rate of about 10⁻⁶ to about 1 cc/m²·day, as measured at 23° C. and 70% relative humidity for 100 hours.

21. The gas barrier film according to claim 1, wherein the gas barrier film has an oxygen transmission rate of about 10⁻⁵ to about 1 cc/m²·day, as measured at 23° C. and 70% relative humidity for 100 hours.

22. A flexible substrate comprising the gas barrier film according to claim 1.

23. A method of manufacturing a gas barrier film, comprising:
coating a graphene solution onto a polymer film to form a graphene layer on the polymer film, the coating comprising at least one selected from spin coating, dip coating, solvent casting, chemical vapor deposition, slot die coating, and spray coating.

24. The method according to claim 13, wherein the graphene solution is coated once or more such that the graphene layer has a thickness of about 0.4 nm to about 5 nm.
